(19) United States
(12) Patent Application Publication
(10) Pub. No.: US 2026/0164712 A1
(43) Pub. Date: Jun. 11, 2026

(54) VERTICAL POWER MOSFET WITH SURROUNDING GATE

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/392,277

(22) Filed: Nov. 18, 2025

Related U.S. Application Data
(60) Provisional application No. 63/729,795, filed on Dec. 9, 2024.

(51) Int. Cl. H10D 30/66; H10D 30/01

(52) U.S. Cl. CPC H10D 30/668; H10D 30/0297

(57) ABSTRACT

A vertical power metal oxide semiconductor field effect transistor includes a volume of semiconductor material, a channel, a source, a drain, and a gate. The volume of semiconductor material presents opposite vertically spaced first and second ends and an outer side perimeter adjacent the first end. The channel extends through the volume of semiconductor material from the first source to the drain. The source is located adjacent the first end. The gate at least substantially surrounds the outer perimeter of the volume of semiconductor material.

### CROSS-REFERENCE TO RELATED APPLICATIONS

The current patent application claims the benefit under 35 U.S.C. § 119(e) of the priority date of U.S. Provisional Application Ser. No. 63/729,795; titled “VERTICAL POWER MOSFET WITH SURROUNDING GATE”; and filed Dec. 9, 2024. The Provisional Application is hereby incorporated by reference, in its entirety, into the current patent application.

### TECHNICAL FIELD

The present disclosure relates to metal oxide semiconductor field-effect transistors and methods of making them, and more particularly, the various examples described herein concern a vertical power metal oxide semiconductor field-effect transistor having a surrounding gate.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY OF THE INVENTION

According to various examples of the present disclosure, a vertical power metal oxide semiconductor field effect transistor includes a volume of semiconductor material, a channel, a source, a drain, and a gate. The volume of semiconductor material presents opposite vertically spaced first and second ends and an outer side perimeter adjacent the first end. The channel extends through the volume of semiconductor material from the source to the drain. The source is located adjacent the first end and extends along at least part of the outer perimeter of the volume of semiconductor material. The gate at least substantially surrounds the outer perimeter of the volume of semiconductor material.

According to various examples of the present disclosure, a method of making a vertical power metal oxide semiconductor field effect transistor includes the steps of: providing a substrate; growing a semiconductor material on the substrate to present a first end spaced from the substrate, an opposite second end adjacent the substrate, and an outer perimeter adjacent the first end; providing a well within the semiconductor material adjacent the first end, the step of providing the well including extending the well at least partly along the outer perimeter of the volume of semiconductor material; positioning a source within the semiconductor material adjacent the first end, the step of positioning the source including extending the source at least partly along the outer perimeter of the semiconductor material; and forming a gate at least substantially around the outer perimeter of the semiconductor material.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates a cross-sectional perspective view of an example vertical power MOSFET having a surrounding gate;

FIGS. 2A-2E illustrate cross-sectional views of the example vertical power MOSFET of FIG. 1 during various stages of a fabrication process; and

FIG. 3 illustrates an example method of making a vertical power MOSFET, such as the vertical power MOSFET of FIGS. 1 and 2A-2E.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a vertical power MOSFET having a surrounding gate, and a method of making a vertical power MOSFET having a surrounding gate. Broadly, the vertical power MOSFET may include a volume of semiconductor material presenting a first end and a second end opposite the first end and an outer perimeter adjacent the first end. The gate may at least substantially surround the outer perimeter of the volume of semiconductor material.

Generally, the vertical power MOSFET may be applicable to various types of power systems such as power generation systems, power distribution systems, power regulation systems, power supplies, power converters, power switches, control systems, and the like. The various types of power systems may be applicable to various types of systems including, for example, power plants, manufacturing systems, power electronics, automotive systems, aircraft, submersibles, transportation systems, radiofrequency (RF) systems, telecom systems, lighting systems, automation systems, computing systems, industrial systems, and the like.

In various examples, the vertical power MOSFET may be rated for voltages ranging from around three (3) volts (V) and forty (40) V for low-voltage applications, forty (40) V and three hundred (300) V for mid-voltage applications, three hundred (300) V and one thousand (1,000) V for high voltage applications, and/or voltages exceeding one thousand (1,000) V for very high voltage applications, without limitation.

The gate surrounding the outer perimeter of the volume of semiconductor material may enable the vertical power MOSFET to have a higher current rating compared to conventional MOSFETs. The higher current rating may be, for example, about four (4) times greater (or more) than a typical current rating for MOSFETS of the same size. The vertical power MOSFET may be sized similarly to conventional power MOSFETs, thus increasing power throughput without occupying additional space. Additionally, the higher current rating may improve MOSFET reliability, reduce switching times, and reduce current leakage.

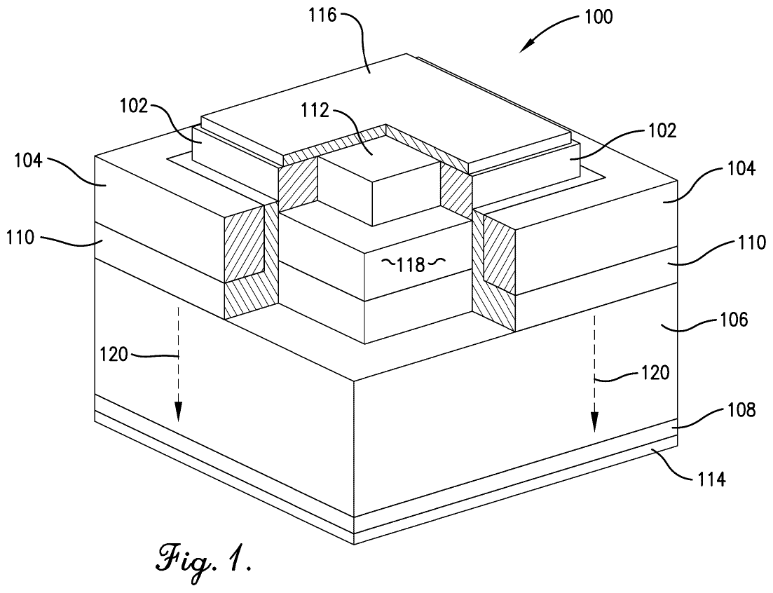

FIG. 1 illustrates a cross-sectional perspective view of an example vertical power MOSFET 100. The MOSFET 100 may generally include a source 102, a gate 104, a volume of semiconductor material 106, a doped substrate material 108, a gate oxide 110, a body contact 112, a drain contact 114, a source/well contact 116, and a well 118. The volume of semiconductor material 106 presents a first end spaced apart from the substrate 108 and a second end opposite the first end and adjacent to the substrate 108. The volume of semiconductor material 106 may present an outer side perimeter adjacent the first end. In the illustrated example, the outer side perimeter of the volume of semiconductor material extends from the first end and is spaced from the second end. The volume of semiconductor material 106 may be constructed from or include an N-type epitaxial semiconductor material.

The source 102, gate 104, gate oxide 110, and well 118 may present respective outer perimeters. The gate oxide 110 may be interposed between the outer perimeter of the volume of semiconductor material 106 and the gate 104. The gate oxide 110 may contact the volume of semiconductor material 106. The gate 104 and gate oxide 110 may extend continuously about the volume of semiconductor material 106, although certain aspects of the example MOSFET contemplate the gate 104 and/or gate oxide 110 being discontinuous. In such alternatives, the gate 104 and/or gate oxide 110 may extend substantially about the perimeter so as to essentially surround the volume of semiconductor material. In the illustrated example, the gate 104 and gate oxide 110 are spaced from the first end of the volume of semiconductor material 106, although the gate 104 and/or gate oxide 110 may, in accordance with some aspects, alternatively extend from the first end.

The source 102 may be adjacent the first end of the volume of semiconductor material 106. In the illustrated example, the source 102 extends from the first end. The source 102 may extend at least partly along the outer semiconductor perimeter so as to contact the gate oxide 110. In the illustrated example, the source 102 may extend continuously around the perimeter so that the source 102 and gate oxide 110 are in substantial or continuous (depending on the extent to which the gate oxide 110 extends about the perimeter) engagement along the perimeter. The source 102 may encircle (or at least substantially surround) the body contact 112.

The well 118 may be located adjacent the first end of the volume of semiconductor material 106 and interiorly of the gate 104, such that the gate 104 and the gate oxide 110 circumscribe the well. In various examples, the body contact 112 and well 118 may be formed as a single body, where the well 118 may be considered a first well portion spaced from the first end of the volume of semiconductor material 106 and the body contact 112 may be considered a second well portion located between the first well portion and first end. The first well portion of the well 118 may extend at least partly along the outer semiconductor perimeter so as to contact the gate oxide 110. In the illustrated example, the well 118 may extend continuously around the perimeter so that the well 118 and gate oxide 110 are in substantial or continuous (depending on the extent to which the gate oxide 110 extends about the perimeter) engagement along the perimeter. The well 118 may extend continuously between the circumscribing gate oxide 110. The body contact (or second well portion) 112 may extend continuously between the source 102. The source 102 may be interposed between the body contact 112 and the gate 104.

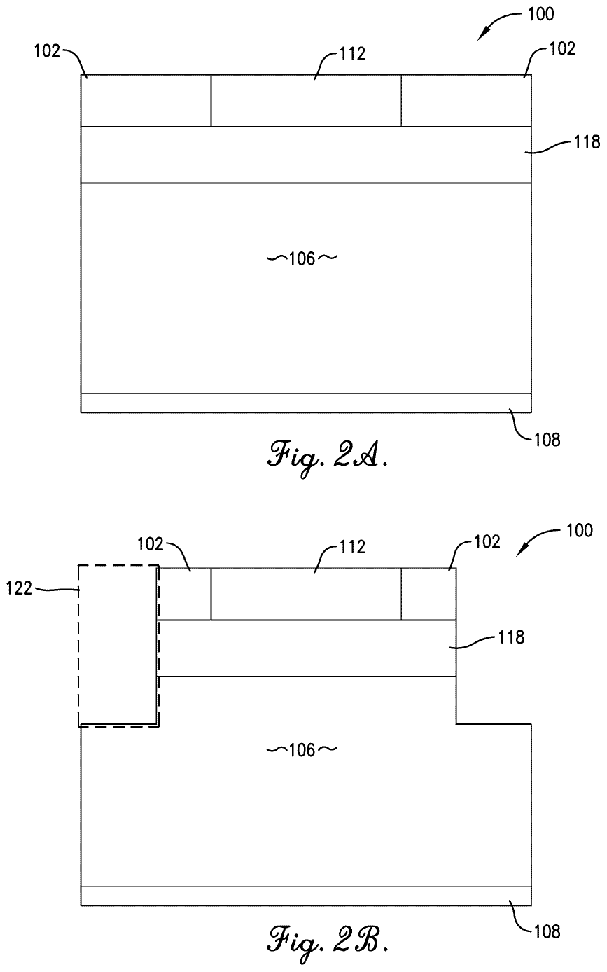

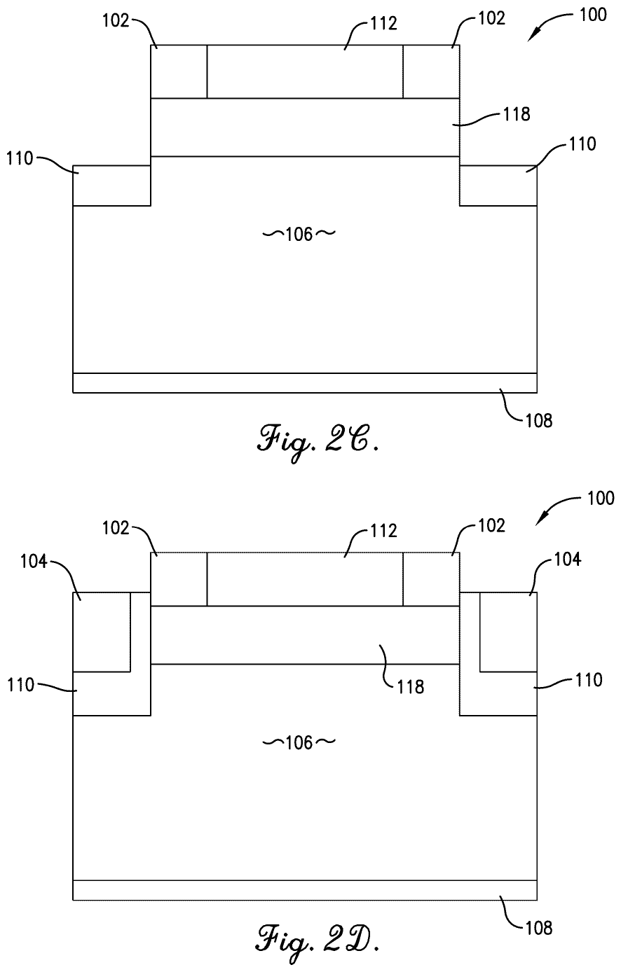

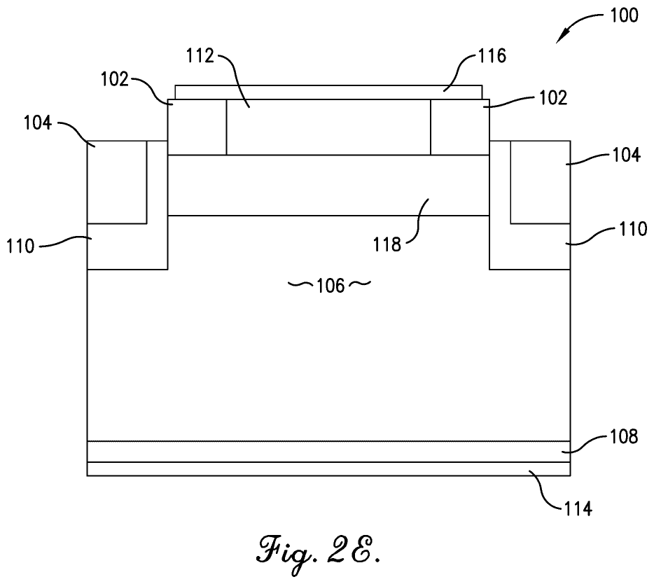

In various examples, the volume of semiconductor material 106 may include a perimetrical trench (e.g., trench 122 as shown in FIG. 2B) adjacent the first end of the volume of semiconductor material 106. The gate 104 and the gate oxide 110 may be located within the trench (e.g., as shown in FIG. 2D). The trench may present a base and an inner upright side extending between the base and the first end of the volume of semiconductor material 106. The gate oxide 110 may line the base and upright side of the trench (e.g., as shown in FIG. 2D).

Although the outer perimeters of the various components of the MOSFET 100 (e.g., the source 102, the gate 104, the volume of semiconductor material 106, the gate oxide 110, and the well 118) are shown to be generally rectangular, it is contemplated that the outer perimeters may be generally circular or elliptical, or may present another polygonal shape, such as a triangle, square, pentagon, hexagon, octagon, and the like, without departing from the scope of the present disclosure.

Additionally, the volume of semiconductor material 106 presents a first side, a second side opposite the first side, a third side adjacent the first and second sides, and a fourth side adjacent the first and second sides and opposite the third side. The outer perimeter may encompass the first, second, third, and fourth sides. It will also be appreciated that the sides of the illustrated volume of semiconductor material 106 are defined herein merely to represent a portion of semiconductor material relative to the illustrated device. In practice, the volume of semiconductor may extend beyond the bounds illustrated in the drawings (leftward, rightward, frontward, and backward when viewing FIGS. 2-6) to present additional semiconductor material in which additional devices may be provided. Such additional devices may be MOSFETs (which may be similarly or alternatively constructed to the MOSFET 100) or may be entirely different devices providing different operations or functions than the MOSFET 100.

The various structures and materials of the MOSFET 100 may be implanted (using, e.g., an ion implanter), deposited, or otherwise provided using a suitable technique in or on respective subvolumes of the volume of semiconductor material 106. These structures and materials and their sizes and positions may vary, but may generally include the following. The semiconductor material may be constructed from or include an N material and may be grown or otherwise formed on the substrate 108. The source 102 may be constructed from or include an N+ material and may be located at the first end of the volume of semiconductor material 106 and generally opposite the substrate 108. The doped substrate material 108 may be constructed from or include an N+ material and may be located at the second end of the volume of semiconductor material 106. The doped substrate material 108 may operate as a drain of the MOSFET 100. The body contact 112 may be constructed from or include a P+ material and may be located adjacent to the source 102. The well 118 may be constructed from or include a P material and may be located below and adjacent to the source 102 and the body contact 112.

The source/well contact 116 may be constructed from or include a conductive material (e.g., copper, aluminum, and the like) and may be located above and adjacent (and in engagement with) the source 102 and the body contact 112. The drain contact 114 may be constructed from or include a conductive material (e.g., copper, aluminum, and the like) and may be located below and adjacent the substrate 108.

The gate oxide 110 may include a layer of dielectric material (e.g., silicon dioxide (SiO2)) and may be provided the outer perimeter of the volume of semiconductor material 106. The gate oxide may circumscribe continuously the outer perimeter of the well 118, and at least partially over an outer perimeter of the source 102.

A channel 120 may extend through the volume of semiconductor material 106 from the first end and the second end of the volume of semiconductor material 106 and between the sides of the volume of semiconductor material 106. With the illustrated construction, the channel 120 is formed at least substantially or continuously (depending on the extent of contact between the source 102 and well 118 with the gate oxide 110) around the outer perimeter. The channel 120 may enable a flow of electrical energy between the source contact 116 and the drain contact 114 when a voltage is applied to the gate 104.

It will be appreciated that the example MOSFET is an N-channel MOSFET. However, certain aspects of the example MOSFET might be applicable to P-channel MOSFETs.

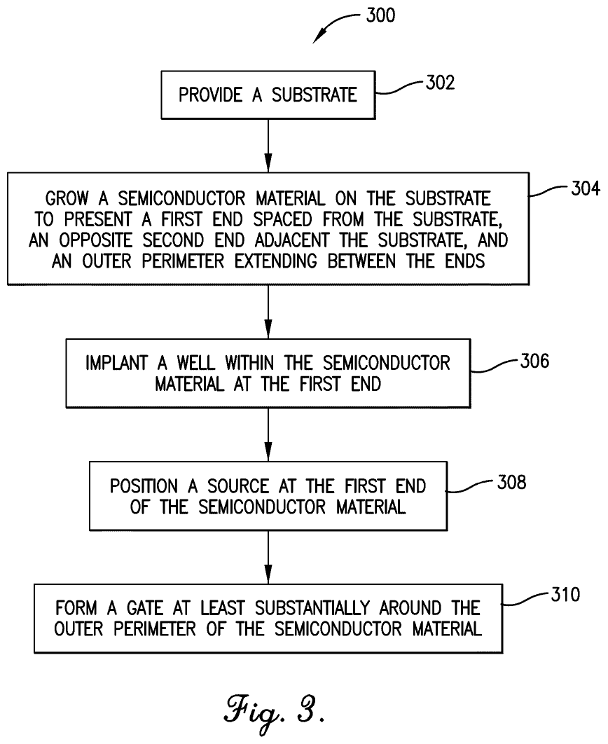

FIGS. 2A-2E illustrate the example MOSFET 100 during various fabrication stages. The steps performed in the fabrication stages are described in more detail below in connection with the method 300 of FIG. 3. As shown in FIG. 2A, the volume of semiconductor material 106 is grown or otherwise deposited on the substrate 108. Subsequent to forming the volume of semiconductor material 106, the source 102, well 118, and body contact 112, may be implanted into (or otherwise provided within) the volume of semiconductor material 106 adjacent the first end thereof.

As shown in FIG. 2B, a perimetrical trench 122 may be formed in the volume of semiconductor material 106 through, for example, an etching process, although the trench 122 may be using an alternative suitable technique. A continuous portion of the semiconductor material 106 may be etched to present the outer perimeter of the semiconductor material 106. The trench 122 may be located adjacent the first end of the semiconductor material 106 and may extend toward the second end beyond the well 118. The trench 122 may present a base (e.g., a shoulder or horizonal (when viewing the drawing figures) portion) and an inner upright side (e.g., a vertical portion adjacent the well 118 and the source 102).

As shown in FIG. 2C, the gate oxide 110 may be grown or otherwise formed on the semiconductor material 106. The gate oxide 110 may be formed within the trench 122. As shown in FIG. 2D, the gate oxide may line the base and the upright side of the trench 122. The gate 104 may be placed within the trench 122, where the gate oxide 110 may be interposed between the outer perimeter of the volume of semiconductor material and the gate 102.

As shown in FIG. 2E, the drain contact 114 may be positioned below the substrate 108, and the source/well contact 116 may be positioned above the source 112 and the body contact 112.

Referring to FIG. 3, an example method 300 of making a vertical power MOSFET having a surrounding gate may include the following operations. References are also made to FIGS. 2A-2E showing the results of certain of the steps of the method 300, as well as the example MOSFET 100 which may be made using the method 300.

At step 302, a substrate is provided. The substrate may correspond to the doped substrate material 108 of FIGS. 1 and 2A-2E. The substrate may be constructed from or include an N+ material.

At step 304, a semiconductor material is grown or otherwise deposited on the substrate to present a first end spaced from the substrate and an opposite second and adjacent the substrate. The semiconductor material may present an outer perimeter adjacent the first end, which in the illustrated example is formed by etching a trench adjacent the first end. The semiconductor material may correspond to the volume of semiconductor material 108 as shown in FIGS. 1 and 2A-2E. The substrate may be located at the second end of the semiconductor material The semiconductor material may be constructed from or include an N-type epitaxial semiconductor material.

At step 306, a well may be implanted (using, e.g., an ion implanter), deposited, or otherwise provided using a suitable technique within the semiconductor material at the first end. The body of material forming the well may include the illustrated well 118 and body contact 112 as shown in FIGS. 1 and 2A-2E. The well and body contact may be constructed from or include P material. In the illustrated example, the well 118 has a lower dopant concentration than the body contact 112. The body forming the well and body contact may be located adjacent the first end of the volume of semiconductor material and at least in part interiorly of the gate (e.g., as shown in FIGS. 1, 2D, and 2E).

At step 308, a source is positioned at the first end of the semiconductor material The source may correspond to the source 102 as shown in FIGS. 1 and 2A-2E. The source may be implanted (using, e.g., an ion implanter), deposited, or otherwise provided using a suitable technique in or on the first end of the semiconductor material. The source may continuously circumscribe the well. The source may be constructed form or include N+ material.

At step 310, a gate is formed at least substantially around the outer perimeter of the semiconductor material. The gate may correspond to the gate 104 as shown in FIGS. 1 and 2A-2E. The gate and the gate oxide may extend along the source and the well.

In various examples, the method 300 further includes interposing a gate oxide between the outer perimeter of the semiconductor material and the gate. The gate oxide may correspond to the gate oxide 110 as shown in FIGS. 1 and 2A-2E. The gate and gate oxide may extend continuously about the perimeter of the semiconductor material.

In various examples, the method 300 further includes forming a perimetrical trench about the perimeter of the semiconductor material adjacent the first end of the semiconductor material. The trench may correspond to the trench 122 as shown in FIG. 2B. The trench may be formed by etching the volume of semiconductor material, as described in connection with FIG. 2B, prior to the gate and gate oxide being provided.

The step of interposing the gate oxide may include forming an oxide layer (e.g., the gate oxide 110 as shown in FIG. 2D) along a bottom and an inner side of the trench. The step 310 of forming the gate may include positioning the gate within the perimetrical trench alongside the oxide layer. The step 308 of positioning the source may include continuously circumscribing the source about the body contact such that the source is interposed between the gate oxide and at least a portion of the well (e.g., the body contact in the illustrated embodiment). The step 306 of implanting the well and the step 308 of positioning the source may be performed before the trench is formed. The trench may extend toward the second end of the semiconductor material beyond the well (e.g., as shown in FIG. 2B).

Additional processing may be performed as desired.

### Feature Combinations

According to various examples of the present disclosure, a vertical power metal oxide semiconductor field effect transistor may include a volume of semiconductor material, a channel, a source, a drain, and a gate. The volume of semiconductor material may present opposite vertically spaced first and second ends and an outer side perimeter adjacent the first end. The channel may extend through the volume of semiconductor material from the source to the drain. The source may be located adjacent the first end and may extend along at least part of the outer perimeter of the volume of semiconductor material. The gate may at least substantially surround the outer perimeter of the volume of semiconductor material.

In combination with the example, the outer perimeter of the volume of semiconductor material may be generally rectangular.

In combination with any of the previous examples, a gate oxide may be interposed between the outer perimeter of the volume of semiconductor material and the gate, and the gate and the gate oxide may extend continuously about the volume of semiconductor material.

In combination with any of the previous examples, the volume of semiconductor material may include a perimetrical trench adjacent the first end of the volume of semiconductor material. The gate and a gate oxide may be located within the trench.

In combination with any of the previous examples, a trench may present a base and an inner upright side extending between the base and a first end of a volume of semiconductor material. A gate oxide may line the base and upright side of the trench.

In combination with any of the previous examples, a well may be located adjacent the first end of the volume of semiconductor material and interiorly of the gate. At least part of the well may extend at least partly along the outer perimeter of the volume of semiconductor material such that the gate and a gate oxide circumscribe the well.

In combination with any of the previous examples, the source may be interposed between at a least a portion a well and the gate.

In combination with any of the previous examples, the source may continuously circumscribe at least a portion of a well.

In combination with any of the previous examples, a well may include a first portion extending continuously interiorly of the gate. The well may include a second contact portion extending continuously between the source.

In combination with any of the previous examples, the volume of semiconductor material may include an N-type semiconductor material.

In combination with any of the previous examples, a well may be located adjacent the first end of the volume of semiconductor material and interiorly of the gate. At least part of the well may extend at least partly along the outer perimeter of the volume of semiconductor material such that the gate at least substantially surrounds the well.

In combination with any of the previous examples, a first portion of a well may include a P-type material implanted into a volume of semiconductor material. A second contact portion of the well may include a P+ material implanted into the volume of semiconductor material above the first portion of the well. The source may include an N+ material implanted into the volume of semiconductor material around the second contact portion of the well. The drain may include an N+ substrate.

According to various examples of the present disclosure, a method of making a vertical power metal oxide semiconductor field effect transistor may include the steps of: providing a substrate; growing a semiconductor material on the substrate to present a first end spaced from the substrate, an opposite second end adjacent the substrate, and an outer perimeter adjacent the first end; providing a well within the semiconductor material adjacent the first end, the step of providing the well including extending the well at least partly along the outer perimeter of the volume of semiconductor material; positioning a source within the semiconductor material adjacent the first end, the step of positioning the source including extending the source at least partly along the outer perimeter of the volume of semiconductor material; and forming a gate at least substantially around the outer perimeter of the semiconductor material.

In combination with any of the previous examples, a method of making a vertical power metal oxide semiconductor field effect transistor may include: interposing a gate oxide between the outer perimeter of the semiconductor material and the gate. The step of forming the gate and the step of interposing the gate oxide may include extending the gate and gate oxide continuously about the perimeter of the semiconductor material.

In combination with any of the previous examples, a method of making a vertical power metal oxide semiconductor field effect transistor may include: forming a perimetrical trench about the perimeter of the semiconductor material adjacent the first end thereof. A step of interposing a gate oxide may include the step of forming an oxide layer along a bottom and inner side of the trench. The step of forming a gate may include the step of positioning the gate within the perimetrical trench alongside the oxide layer.

In combination with any of the previous examples, the step of positioning a source may include the step of continuously circumscribing the source about at least a portion of the well such that the source may be interposed between a gate oxide and the at least a portion of the well.

In combination with any of the previous examples, steps of implanting a well and positioning a source may be performed before a step of forming a trench. The trench may extend toward a second end of a semiconductor material beyond the well.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., metal oxide semiconductor field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment (or example) may also be included in other embodiments (or examples) but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A vertical power metal oxide semiconductor field effect transistor (MOSFET), comprising:
a volume of semiconductor material presenting opposite vertically spaced first and second ends and an outer side perimeter adjacent the first end;
a source located adjacent the first end and extending along at least part of the outer perimeter of the volume of semiconductor material;
a drain;
a channel extending through the volume of semiconductor material from the source to the drain; and
a gate at least substantially surrounding the outer perimeter of the volume of semiconductor material.

2. The vertical power MOSFET of claim 1,
the outer perimeter of the volume of semiconductor material being generally rectangular.

3. The vertical power MOSFET of claim 1, comprising:
a gate oxide interposed between the outer perimeter of the volume of semiconductor material and the gate, the gate and the gate oxide extending continuously about the volume of semiconductor material.

4. The vertical power MOSFET of claim 3,
the volume of semiconductor material including a perimetrical trench adjacent the first end,
the gate and gate oxide being located within the trench.

5. The vertical power MOSFET of claim 4,
the trench presenting a base and an inner upright side extending between the base and the first end,
the gate oxide lining the base and upright side of the trench.

6. The vertical power MOSFET of claim 4, comprising:
a well located adjacent the first end and interiorly of the gate,
at least part of the well extending at least partly along the outer perimeter of the volume of semiconductor material such that the gate and gate oxide circumscribe the well.

7. The vertical power MOSFET of claim 6,
the source being interposed between a portion the well and the gate.

8. The vertical power MOSFET of claim 7,
the source circumscribing continuously the portion of the well.

9. The vertical power MOSFET of claim 6,
the well including a first portion extending continuously between the circumscribing gate oxide,
the well including a second contact portion extending continuously between the source.

10. The vertical power MOSFET of claim 9,
the volume of semiconductor material including an N-type semiconductor material.

11. The vertical power MOSFET of claim 10,
the first portion of the well including a P-type material implanted into the volume of semiconductor material,
the second contact portion of the well including a P+material implanted into the volume of semiconductor material above the first portion of the well,
the source including an N+ material implanted into the volume of semiconductor material around the second contact portion of the well, and
the drain including an N+ substrate.

12. The vertical power MOSFET of claim 1,
a well located adjacent the first end and interiorly of the gate,
at least part of the well extending at least partly along the outer perimeter of the volume of semiconductor material such that the gate at least substantially surrounds the well.

13. The vertical power MOSFET of claim 12,
the source being interposed between a portion of the well and the gate.

14. The vertical power MOSFET of claim 13,
the source circumscribing continuously the portion of the well.

15. The vertical power MOSFET of claim 12,
the well including a first portion extending continuously interiorly of the gate,
the well including a second contact portion extending continuously between the source.

16. A method of making a vertical power metal oxide semiconductor field effect transistor (MOSFET) comprising the steps of:
providing a substrate;
growing a semiconductor material on the substrate to present a first end spaced from the substrate, an opposite second end adjacent the substrate, and an outer perimeter adjacent the first end;
providing a well within the semiconductor material adjacent the first end,
the step of providing the well including extending the well at least partly along the outer perimeter of the volume of semiconductor material;
positioning a source within the semiconductor material adjacent the first end,
the step of positioning the source including extending the source at least partly along the outer perimeter of the volume of semiconductor material; and
forming a gate at least substantially around the outer perimeter of the semiconductor material.

17. The method of claim 16, further comprising:
interposing a gate oxide between the outer perimeter of the semiconductor material and the gate,
the step of forming the gate and the step of interposing the gate oxide including extending the gate and gate oxide continuously about the perimeter of the semiconductor material.

18. The method of claim 17, further comprising:
forming a perimetrical trench about the perimeter of the semiconductor material adjacent the first end thereof,
the step of interposing the gate oxide including the step of forming an oxide layer along a bottom and inner side of the trench,
the step of forming the gate including the step of positioning the gate within the perimetrical trench alongside the oxide layer.

19. The method of claim 18,
the step of positioning the source including the step of continuously circumscribing the source about at least a portion of the well such that the source is interposed between the gate oxide and the at least a portion of the well.

20. The method of claim 19,
the steps of providing the well and positioning the source being performed before the step of forming the trench, with the trench extending toward the second end of the semiconductor material beyond the well.
